(19) United States
(12) Patent Application Publication
(10) Pub. No.: US 2025/0225288 A1
(43) Pub. Date: Jul. 10, 2025

(54) Comparing an Autonomy Stack with an Updated Autonomy Stack in a Simulator

(71) Applicant: Oxa Autonomy Ltd, Oxford (GB)

(72) Inventors: David Brian Lomas, Oxford (GB); Robert Ruck, Oxford (GB)

(73) Assignee: Oxa Autonomy Ltd, Oxford (GB)

(21) Appl. No.: 18/408,253

(22) Filed: Jan. 9, 2024

(51) Int. Cl. G06F 30/15

(52) U.S. Cl. CPC G06F 30/15

(57) ABSTRACT

The present invention relates to a computer-implemented method of comparing an autonomy stack with an updated autonomy stack in a simulator. The computer-implemented method comprising: retrieving a portion of telemetry data recorded by the autonomy stack, the telemetry data representing a real-world environment in which an autonomous vehicle operated, the autonomous vehicle controlled by the autonomy stack; generating a simulation of the real-world environment using the telemetry data; providing an ego-vehicle in the simulation at a position of the autonomous vehicle associated with the telemetry data, the ego-vehicle controlled in the simulation by the autonomy stack; providing an updated ego-vehicle in the simulation, the updated ego-vehicle controlled in the simulation by the updated autonomy stack; generating a real-time simulation by positionally synchronising the ego-vehicle with the updated ego-vehicle; and displaying the real-time simulation on a display device.

### FIELD

The subject-matter of the present disclosure relates to comparing an autonomy stack with an updated autonomy stack in a simulator, transitory, or non-transitory, computer-readable media, and simulation systems.

### BACKGROUND

Simulators are often used in the development of autonomous vehicles (AV). Typically, when an AV operates in a real-world environment, it includes sensors to capture sensor data representing the real-world environment. This sensor data can be used to generate a simulation of the real-world environment.

During development, an autonomy stack of the AV may be updated, or modified in order to make the autonomy stack less susceptible to infractions such as collisions between the AV and other objects. The updated AV can be provided in a simulator together with the real-world environment. In this way, it is possible to test how the updated autonomy stack responds to stimulus, e.g. objects, in the real-world environment.

However, it is difficult to compared responses of the updated autonomy stack with responses of a previous vehicle of the autonomy stack to the same stimulus in the simulation.

It is an aim of the present invention to address such problems and improve on the prior art.

### SUMMARY

According to an aspect of the present disclosure, there is provided a computer-implemented method of comparing an autonomy stack with an updated autonomy stack in a simulator, the computer-implemented method comprising: retrieving a portion of telemetry data recorded by the autonomy stack, the telemetry data representing a real-world environment in which an autonomous vehicle operated, the autonomous vehicle controlled by the autonomy stack; generating a simulation of the real-world environment using the telemetry data; providing an ego-vehicle in the simulation at a position of the autonomous vehicle associated with the telemetry data, the ego-vehicle controlled in the simulation by the autonomy stack; providing an updated ego-vehicle in the simulation, the updated ego-vehicle controlled in the simulation by the updated autonomy stack; generating a real-time simulation by positionally synchronising the ego-vehicle with the updated ego-vehicle; and displaying the real-time simulation on a display device.

In an embodiment, the displaying the real-time simulation on the display device comprises: displaying the updated ego-vehicle as a vehicle; and displaying the ego-vehicle as a ghost image of a vehicle.

In an embodiment, the generating a real-time simulation by positionally synchronising the ego-vehicle with the updated ego-vehicle comprises: adjusting a time of the ego-vehicle.

In an embodiment, the generating a real-time simulation by positionally synchronising the ego-vehicle with the updated ego-vehicle comprises: adjusting a time of the updated ego-vehicle.

In an embodiment, the generating a real-time simulation by positionally synchronising the ego-vehicle with the updated ego-vehicle is generating a real-time simulation by positionally synchronising the ego-vehicle to within a threshold distance of the updated ego-vehicle.

In an embodiment, the threshold distance is a longitudinal threshold distance.

In an embodiment, the computer-implemented method further comprises: comparing a position of the updated ego-vehicle to a route destination; and retrieving a subsequent portion of telemetry data recorded by the autonomy stack.

In an embodiment, the real-world environment includes at least one object, and wherein the generating a simulation of the real-world environment using the telemetry data comprises: generating the simulation of the real-world environment including the at least one object.

In an embodiment, the at least object is selected from a list of objects including: a pedestrian, a non-human animal, a lane boundary, a building, and a vehicle.

In an embodiment, the computer-implemented method further comprises: adjusting a time of the at least one object to be temporally synchronised with the updated ego vehicle.

In an embodiment, the telemetry data is derived from at least one sensor.

In an embodiment, the at least one sensor is selected of sensors including: a camera, a LIDAR sensor, and a RADAR sensor.

According to an aspect of the present disclosure, there is provided a transitory, or non-transitory, computer-readable medium, having instructions stored thereon that when executed by at least one processor cause the at least one processor to perform the computer-implemented method of any preceding aspect or embodiment.

According to an aspect of the present disclosure, there is provided a simulation system, comprising: storage storing telemetry data recorded by an autonomy stack, the telemetry data representing a real-world environment in which the autonomous vehicle operated, the autonomous vehicle controlled by the autonomy stack, and storing instructions; a display device; and at least one processor configured to processor the instructions to: retrieve a portion of the telemetry data from the storage, generate a simulation of the real-world environment using the telemetry data, provide an ego-vehicle in the simulation at a position of the autonomous vehicle associated with the telemetry data, the ego-vehicle controlled in the simulation by the autonomy stack, provide an updated ego-vehicle in the simulation, the updated ego-vehicle controlled in the simulation by the updated autonomy stack, generate a real-time simulation by positionally synchronising the ego-vehicle with the updated ego-vehicle, and display the real-time simulation on the display device.

### BRIEF DESCRIPTION OF DRAWINGS

The subject-matter of the present disclosure is best described with reference to the accompanying figures, in which:

FIG. 1 shows a schematic view of an autonomous vehicle;

FIG. 2 shows a block diagram of a simulation system, according to one or more embodiments;

FIG. 3 shows a flow chart detailing a computer-implemented method of comparing an autonomy stack and an updated autonomy stack in the simulator system of FIG. 2, according to one or more embodiments;

FIG. 4 shows a screen shot from a display device of FIG. 2, according to one or more embodiments;

FIG. 5 shows a similar screen shot as shown in FIG. 4; and

FIG. 6 shows a flow chart summarising a computer-implemented method of comparing an autonomy stack and an updated autonomy stack in a simulator, according to one or more embodiments.

### DESCRIPTION OF EMBODIMENTS

At least some of the example embodiments described herein may be constructed, partially or wholly, using dedicated special-purpose hardware. Terms such as ‘component’, ‘module’ or ‘unit’ may relate to software instructions. In some embodiments, the described elements may be configured to reside on a tangible, persistent, addressable storage medium and may be configured to execute on one or more processors. The one or more processors may be graphical processing units. These functional elements may in some embodiments include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. Although the example embodiments have been described with reference to the components, modules and units discussed herein, such functional elements may be combined into fewer elements or separated into additional elements. Various combinations of optional features have been described herein, and it will be appreciated that described features may be combined in any suitable combination. In particular, the features of any one example embodiment may be combined with features of any other embodiment, as appropriate, except where such combinations are mutually exclusive. Throughout this specification, the term “comprising” or “comprises” means including the component(s) specified but not to the exclusion of the presence of others.

The embodiments described herein may be embodied as sets of instructions stored as electronic data in one or more storage media. Specifically, the instructions may be provided on a transitory or non-transitory computer-readable media. When executed by the processor, the processor is configured to perform the various methods described in the following embodiments. In this way, the methods may be computer-implemented methods.

Whilst the following embodiments provide specific illustrative examples, those illustrative examples should not be taken as limiting, and the scope of protection is defined by the claims. Features from specific embodiments may be used in combination with features from other embodiments without extending the subject-matter beyond the content of the present disclosure.

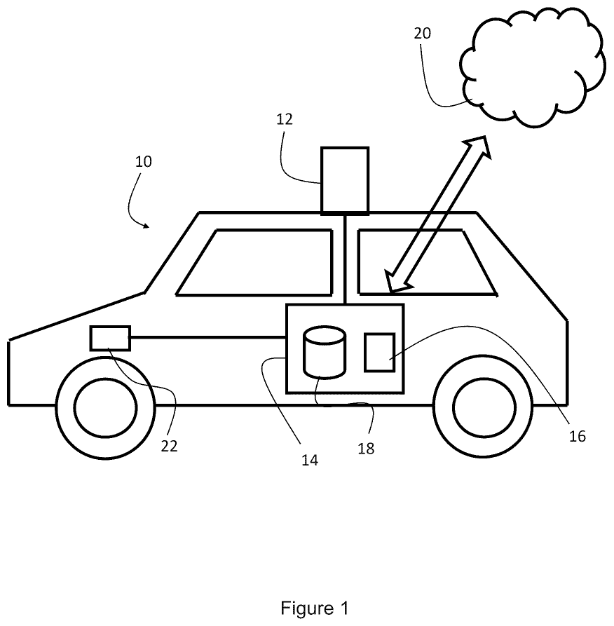

With reference to FIG. 1, an autonomous vehicle (AV) 10 may include a plurality of sensors 12. The sensors 12 may be mounted on a roof of the AV 10, or integrated into the bumpers, grill, bodywork, etc. The sensors 12 may be communicatively connected to a computer 14. The computer 14 may be onboard the AV 10. The computer 14 may include a processor 16 and storage 18. The non-transitory computer-readable media may be located remotely on a different computer and may be communicatively linked to the computer 14 via the cloud 20. The computer 14 may be communicatively linked to one or more actuators 22 for control thereof to move the AV 10. The actuators may include, for example, a motor, a braking system, a power steering system, etc.

The computer 14 includes an autonomy stack for controlling the AV 10. The autonomy stack 34 may control the AV 10 in response to the sensor data. To achieve this, the autonomy stack may include one or more machine learning models. The one or more machine learning models may include an end-to-end model that is trained to provide control commands to actuators of the AV 10 in response to the sensor data. The one or more machine learning models may include machine learning models respectively responsible for perception, planning, and control. This may be in addition to the end-to-end model or as an alternative to the end-to-end model. Perception functions may include object detection and classification based on sensor data. Planning functions may include object tracking and trajectory generation. Control functions including setting control instructions for one or more actuators 22 of the AV 10 to move the AV 10 according to the trajectory.

The sensors 12 may include various sensor types. Examples of sensor types include LiDAR sensors, RADAR sensors, and cameras. Each sensor type may be referred to as a sensor modality. Each sensor type may record data associated with the sensor modality. For example, the LiDAR sensor may record LiDAR modality data.

The data may be referred to as telemetry data which represents a real-world environment in which the AV operates. The real-world environment may represent different real-world scenes. Each scene may include various objects including a pedestrian, a non-human animal, a lane boundary, a building, and a vehicle, for example. Whilst in some scenes there may be no objects, in more scenes there is at least one such object.

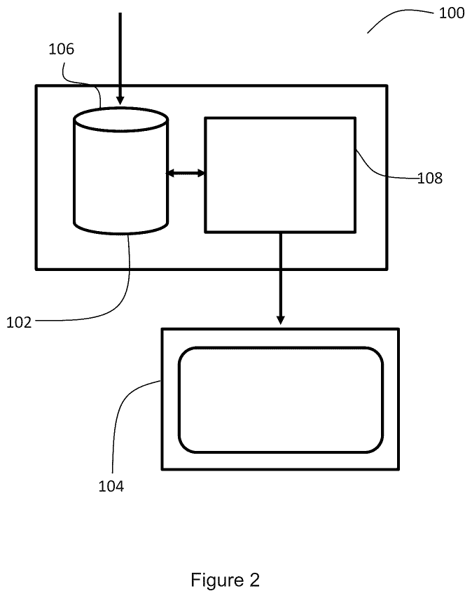

With reference to FIG. 2, a simulation system 100 includes a computer 102 and a display device 104. The term simulation system may be used interchangeably with the term simulator. The computer 102 includes storage 106 and at least one processor 108. The at least one processor may be a graphical processing unit (GPU), for example.

The storage 106 may be configured to receive the telemetry data from the AV 10. The storage therefore stores the telemetry data thereon. The storage 106 also has various electronic data stored thereon in the form of instructions. The storage 106 may be the non-transitory computer-readable medium described above, and having instructions stored thereon that when executed by the at least one processor 108 cause the at least one processor 108 to perform the various computer-implemented methods described below. In addition, the instructions may be provided as transitory computer-readable media when they are being stored on the storage in the form of a download.

One use of the simulator is to test how the autonomy stack responds to the real-world environment represented in a simulation. This can be achieved by providing an ego vehicle in the simulation, which ego vehicle is controlled by the autonomy stack. It is then possible to observe how the ego vehicle responds to the real-world environment. For example, if there are objects in the real-world environment, infractions may occur involving those objects and the ego vehicle. An infraction may be anything that results in anomalous, or undesirable, behaviour of the ego vehicle. For example, an infraction may be selected from a list of infractions including harsh braking, a collision, coming too close to an object, etc. This can be observed on the display device 108, and/or can be extracted in the form of a log file.

As a consequence, an engineering team is able to make modifications or updates to the autonomy stack to reduce the risk of such infractions occurring in future. An updated ego vehicle can be provided in the simulation and controlled by the updated autonomy stack to test its response to the objects. The term “updated autonomy stack” may thus mean a modified version, or updated version, of the autonomy stack.

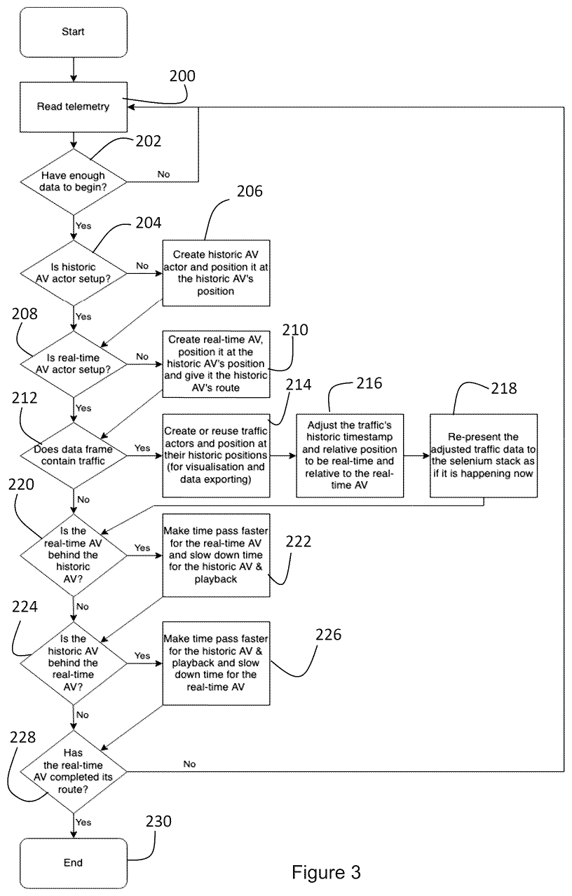

With reference to FIG. 3, a computer-implemented method of comparing an autonomy stack with an updated autonomy stack in the simulator of FIG. 2 is described below.

The method comprises retrieving 200, and reading, a portion of the telemetry data from the storage 106 (FIG. 2). The method may comprise determining 202 if enough data has been retrieved in order to begin with a simulation. An example threshold for “enough data” is when there is sufficient data to be able to change a time of the simulation and the ego vehicle, and/or change a time of the updated ego vehicle so that the ego-vehicle and the updated ego vehicle can be temporally synchronised in the simulation. Another requirement of “enough data” is that the updated ego-vehicle has sufficient data to establish a route.

If it is decided that the portion of telemetry data is insufficient, or not enough, the method comprises retrieving further telemetry data from the storage 106 (FIG. 2). If there is a sufficient data, the method proceeds.

The method may comprise generating a simulation of the real-world environment using the telemetry data. This may include generating the simulation of the real-world environment including any objects that are in the real-world environment that have been captured by the sensors. For example, simulation may represent an urban road including other vehicles.

In proceeding, the method may comprise deciding 204 determining if the ego vehicle is already set up. The ego vehicle may be called other terms such as historic AV actor.

If there is no ego vehicle already in the simulation, the method may comprises creating the ego vehicle and positioning if at the position of the AV 10 in the real world environment when it captured the telemetry data. In this way, the method comprises providing 206 an ego-vehicle in the simulation at a position of the AV 10 associated with the telemetry data. The ego vehicle is controlled in the simulation by the autonomy stack.

Whether the ego vehicle has been provided already, or whether it is provided for the first time, the method proceeds to determining 208 if the updated ego vehicle has already been set up. The term ego vehicle may be used interchangeably with the term real-time AV actor.

If the ego vehicle has not been set up already, the method comprises creating the ego vehicle, position it at a position of the ego vehicle in the simulation, and give it the ego vehicle's route. Expressed more generally, the method comprises providing 210 an updated ego-vehicle in the simulation. The updated ego-vehicle is controlled in the simulation by the updated autonomy stack.

Whether the updated ego vehicle has already been provided or whether it is provided for the first time, the method proceeds to determining 212 whether the simulation, or at least the data frame of the simulation, contains traffic. In other words, the method includes determining if other vehicles are in the simulation.

If there are other vehicles, the method may comprise creating 214 or reusing other vehicle actors and positions them at their respective positions. The respective positions may be their historic positions. This may be for visualisation and data exporting.

Next, the method may comprise adjusting 216 the other vehicle actors' historic timestamps and relative positions to be temporally synchronised with the updated ego vehicle. In other words, a time frame of the other vehicle actors may be adjusted so that it is synchronised with the updated ego vehicle. Therefore, the method may comprise adjusting a time of an object in the simulation to be temporally synchronised with the updated ego vehicle.

Next, the method may comprise presenting 218, or re-presenting, the time adjusted vehicle actors to the updated ego vehicle in the simulation. In other words, the simulation, and the other objects in the simulation, are encountered by the ego-vehicle in a real-time of the updated ego vehicle. Therefore, it is possible to test a response to the updated ego vehicle to the objects in the simulation.

Next, either when it has been determined that there are no other vehicle actors or when the other vehicle actors have been time adjusted and presented to the updated ego vehicle, the method comprises determining if the ego vehicle and the updated ego vehicle are temporally synchronised. More specifically, the method comprises determining 220 if the updated ego vehicle is temporally behind the ego vehicle.

If the updated ego-vehicle is temporally behind the ego-vehicle, the method comprises adjusting 222 a time of the updated ego vehicle so that it is temporally synchronised with the ego vehicle. This may be achieved by making time pass quicker for the updated ego vehicle, or by changing a time stamp of the updated ego vehicle. In addition, time of the ego vehicle can be made to slow down, or a time stamp of the ego-vehicle can be changed.

When the updated ego-vehicle is not temporally behind the ego-vehicle, the method comprises determining 224 if the ego vehicle is temporally behind the updated ego vehicle.

If the ego-vehicle is temporally behind the updated ego-vehicle, the method comprises adjusting 226 a time of the ego-vehicle so that it is temporally synchronised with the updated ego-vehicle. This may be achieved by making time pass quicker for the ego vehicle, or by changing a time stamp of the ego vehicle. In addition, time of the updated ego vehicle can be made to slow down, or a time stamp of the updated ego-vehicle can be changed.

When the description refers to temporally synchronising the updated ego vehicle with the ego vehicle, it means that the ego vehicle and the updated vehicle are within a threshold distance of one another. The threshold distance may be a longitudinal length. The threshold distance may be a multiple of lengths of the updated ego vehicle.

Since the other vehicles in the simulation and the ego vehicle have been time adjusted, the method can be understood as comprising generating a real-time simulation by positionally synchronising the ego-vehicle with the updated ego-vehicle.

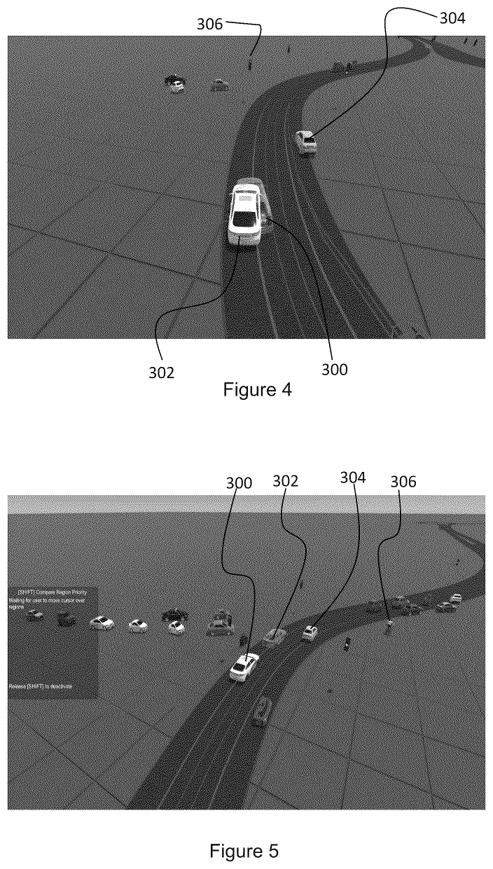

With reference to FIG. 4 and FIG. 5, the method comprises displaying the real-time simulation on the display device 104 (FIG. 2).

The method comprises displaying the ego vehicle 300, the updated ego vehicle 302, and the objects. More specifically, the updated ego vehicle is displayed as a vehicle and the ego vehicle is displayed as a ghost image of a vehicle. More specifically, the vehicle may be a road vehicle, e.g. a car. The objects may include other road vehicles, e.g. cars 304, and pedestrians 306.

Displaying the ego vehicle as a ghost car enables an engineer viewing the scenario to distinguish between the vehicle and the ego vehicle. It is preferable to represent the ego vehicle as the ghost car because it is more important to view the response of the updated ego vehicle to the simulation. However, it is beneficial for the engineer to observe the behaviour of the ego vehicle to the same stimulus in the simulation in real-time so that they can see visually to what extent the updates to the autonomy stack have worked or not.

With further reference to FIG. 3, once the ego vehicle is temporally synchronised with the updated ego vehicle, the method comprises determining 228 if the updated ego vehicle has completed its route. If it has completed its route, the method comprises ending 230 the simulation. If it has not completed its route, the method comprises retrieving a subsequent portion of telemetry data recorded by the autonomy stack. Then the method continues as above.

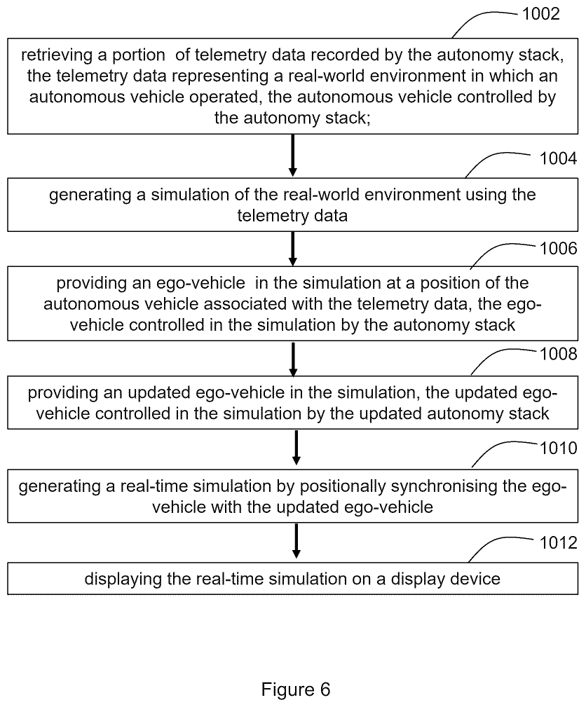

With reference to FIG. 6, the computer-implemented method of comparing an autonomy stack with an updated autonomy stack in a simulator may be summarised as comprising: retrieving 1002 a portion of telemetry data recorded by the autonomy stack, the telemetry data representing a real-world environment in which an autonomous vehicle operated, the autonomous vehicle controlled by the autonomy stack; generating 1004 a simulation of the real-world environment using the telemetry data; providing 1006 an ego-vehicle in the simulation at a position of the autonomous vehicle associated with the telemetry data, the ego-vehicle controlled in the simulation by the autonomy stack; providing 1008 an updated ego-vehicle in the simulation, the updated ego-vehicle controlled in the simulation by the updated autonomy stack; generating 1010 a real-time simulation by positionally synchronising the ego-vehicle with the updated ego-vehicle; and displaying 1012 the real-time simulation on a display device.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfil the functions of several items recited in the claims. The mere fact that certain measures are recited in mutually different dependent claims does not indicate that a combination of these measured cannot be used to advantage. Any reference signs in the claims should not be construed as limiting the scope.

1. A computer-implemented method of comparing an autonomy stack with an updated autonomy stack in a simulator, the computer-implemented method comprising:
retrieving a portion of telemetry data recorded by the autonomy stack, the telemetry data representing a real-world environment in which an autonomous vehicle operated, the autonomous vehicle controlled by the autonomy stack;
generating a simulation of the real-world environment using the telemetry data;
providing an ego-vehicle in the simulation at a position of the autonomous vehicle associated with the telemetry data, the ego-vehicle controlled in the simulation by the autonomy stack;
providing an updated ego-vehicle in the simulation, the updated ego-vehicle controlled in the simulation by the updated autonomy stack;
generating a real-time simulation by positionally synchronising the ego-vehicle with the updated ego-vehicle; and
displaying the real-time simulation on a display device.

2. The computer-implemented method of claim 1, wherein the displaying the real-time simulation on the display device comprises:
displaying the updated ego-vehicle as a vehicle; and
displaying the ego-vehicle as a ghost image of a vehicle.

3. The computer implemented method of claim 1, wherein the generating a real-time simulation by positionally synchronising the ego-vehicle with the updated ego-vehicle comprises:
adjusting a time of the ego-vehicle.

4. The computer-implemented method of claim 1, wherein the generating a real-time simulation by positionally synchronising the ego-vehicle with the updated ego-vehicle comprises:
adjusting a time of the updated ego-vehicle.

5. The computer-implemented method of claim 1, wherein the generating a real-time simulation by positionally synchronising the ego-vehicle with the updated ego-vehicle is generating a real-time simulation by positionally synchronising the ego-vehicle to within a threshold distance of the updated ego-vehicle.

6. The computer-implemented method of claim 5, wherein the threshold distance is a longitudinal threshold distance.

7. The computer-implemented method of claim 1, further comprising:
comparing a position of the updated ego-vehicle to a route destination; and
retrieving a subsequent portion of telemetry data recorded by the autonomy stack.

8. The computer-implemented method of claim 1, wherein the real-world environment includes at least one object, and wherein the generating a simulation of the real-world environment using the telemetry data comprises:
generating the simulation of the real-world environment including the at least one object.

9. The computer implemented method of claim 8, wherein the at least object is selected from a list of objects including:
a pedestrian, a non-human animal, a lane boundary, a building, and a vehicle.

10. The computer-implemented method of claim 8, further comprising:
adjusting a time of the at least one object to be temporally synchronised with the updated ego vehicle.

11. The computer-implemented method of claim 1, wherein the telemetry data is derived from at least one sensor.

12. The computer-implemented method of claim 11, wherein the at least one sensor is selected of sensors including:
a camera, a LIDAR sensor, and a RADAR sensor.

13. A transitory computer-readable medium, having instructions stored thereon that when executed by at least one processor cause the at least one processor to perform the computer-implemented method of claim 1.

14. A simulation system, comprising:
storage storing telemetry data recorded by an autonomy stack, the telemetry data representing a real-world environment in which the autonomous vehicle operated, the autonomous vehicle controlled by the autonomy stack, and storing instructions;
a display device; and
at least one processor configured to processor the instructions to:
retrieve a portion of the telemetry data from the storage,
generate a simulation of the real-world environment using the telemetry data,
provide an ego-vehicle in the simulation at a position of the autonomous vehicle associated with the telemetry data, the ego-vehicle controlled in the simulation by the autonomy stack,
provide an updated ego-vehicle in the simulation, the updated ego-vehicle controlled in the simulation by the updated autonomy stack,
generate a real-time simulation by positionally synchronising the ego-vehicle with the updated ego-vehicle, and
display the real-time simulation on the display device.
